(19) United States
(12) Patent Application Publication
(10) Pub. No.: US 2011/0186120 A1
(43) Pub. Date: Aug. 4, 2011

(54) Textured coating with various feature sizes made by using multiple-agent etchant for thin-film solar cells and/or methods of making the same

(75) Inventor: Alexey Krasnov, Canton, MI (US)

(73) Assignee: Guardian Industries Corp., Auburn Hills, MI (US)

(21) Appl. No.: 12/929,464

(22) Filed: Jan. 26, 2011

Related U.S. Application Data
(63) Continuation-in-part of application No. 12/591,061, filed on Nov. 5, 2009.
Application No. 12/591,061 is a continuation-in-part of application No. 12/929,111, filed on Dec. 30, 2010.

(51) Int. Cl. H01L 31/0216; H01L 31/0236; H01L 31/18

(52) U.S. Cl. 136/256; 438/85; 438/96; 257/E31.126; 257/E31.094

(57) ABSTRACT

Certain example embodiments of this invention relate to solar cell devices, and/or methods of making the same. More particularly, certain example embodiments relate to a front transparent conductive electrode for solar cell devices (e.g., micro-morph silicon thin-film solar cells), and/or methods of making the same. The electrode of certain example embodiments may include a textured transparent conductive oxide (TCO) layer. The textured layer and/or coating may include at least two feature sizes, wherein at least one type of feature is comparable in size to the wavelength of solar light absorbed by the amorphous portion of the micro-morph silicon solar cell, and the other feature size being comparable to that of micro-crystalline portion. Double-agent etchants may be used to produce such different features sizes. Using a textured TCO-based layer having different feature sizes may improve the efficiency of the solar cell.

### FIELD OF THE INVENTION

This application is a Continuation-in-Part (CIP) of U.S. application Ser. No. 12/591,061, filed Nov. 5, 2009, and U.S. application Ser. No. 12/929,111, filed Dec. 30, 2010, the disclosures of which are hereby incorporated by reference.

### FIELD OF THE INVENTION

Certain example embodiments of this invention relate to solar cell devices, and/or methods of making the same. More particularly, certain example embodiments relate to a front transparent conductive electrode for solar cell devices (e.g., amorphous silicon or a-Si solar cell devices, micro-morph silicon thin-film solar cell devices, etc.), and/or methods of making the same. The solar cells may include, for example, a textured transparent conductive oxide (TCO)-based layer and/or coating in certain instances. The textured TCO-based layer and/or coating of certain example embodiments may include at least two feature sizes, wherein at least one type of feature is of a size corresponding to the wavelength of solar light absorbed by the crystalline portion of the micro-morph thin-film silicon solar cell, and the other type corresponds in size to the wavelength of solar light absorbed by the amorphous portion of the micro-morph thin-film silicon solar cell. In certain example embodiments, the use of double-agent etchants may result in an appropriate texturing of a TCO layer, e.g., such that the TCO layer has more than one feature size, potentially improving the efficiency of the solar cell.

### BACKGROUND AND SUMMARY OF EXAMPLE EMBODIMENTS OF THE INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front electrode or contact. Typically, the transparent front electrode is made of a pyrolytic transparent conductive oxide (TCO) such as zinc oxide or tin oxide formed on a substrate such as a glass substrate. In many instances, the transparent front electrode is formed of a single layer using a method of chemical pyrolysis where precursors are sprayed onto the glass substrate at approximately 400 to 600 degrees C. Typical pyrolitic fluorine-doped tin oxide TCOs as front electrodes may be about 1000 nm thick, which provides for a sheet resistance (Rs) of about 15 ohms/square. To achieve high output power, a front electrode having a low sheet resistance and good ohm-contact to the cell top layer, and allowing maximum solar energy in certain desirable ranges into the absorbing semiconductor film, are desired.

Unfortunately, photovoltaic devices (e.g., solar cells) with only such conventional TCO front electrodes suffer from various problems.

First, a pyrolitic fluorine-doped tin oxide TCO about 1000 nm thick as the entire front electrode has a sheet resistance (Rs) of about 15 ohms/square, which is rather high for the entire front electrode. A lower sheet resistance (and thus better conductivity) would be desired for the front electrode of a photovoltaic device. A lower sheet resistance may be achieved by increasing the thickness of such a TCO, but this will cause transmission of light through the TCO to drop thereby reducing output power of the photovoltaic device.

Second, conventional TCO front electrodes such as pyrolytic tin oxide based TCOs allow a significant amount of infrared (IR) radiation to pass therethrough, thereby allowing it to reach the semiconductor or absorbing layer(s) of the photovoltaic device. This IR radiation causes heat, which increases the operating temperature of the photovoltaic device thereby decreasing the output power thereof.

Third, conventional TCO front electrodes such as pyrolytic tin oxide tend to reflect a significant amount of light in the region of from about 450-700 nm so that less than about 80% of useful solar energy reaches the semiconductor absorbing layer; this significant reflection of visible light is a waste of energy and leads to reduced photovoltaic module output power. Due to the TCO absorption and reflections of light which occur between the TCO (refractive index n about 1.8 to 2.0 at 550 nm) and the thin film semiconductor (n about 3.0 to 4.5), and between the TCO and the glass substrate (n about 1.5), the TCO coated glass at the front of the photovoltaic device typically allows less than 80% of the useful solar energy impinging upon the device to reach the semiconductor film which converts the light into electric energy.

Fourth, the rather high total thickness (e.g., 400 nm) of the front electrode in the case of a 1000 nm thick tin oxide TCO, leads to high fabrication costs.

Fifth, the process window for forming a zinc oxide or tin oxide TCO for a front electrode is both small and important. In this respect, even small changes in the process window can adversely affect conductivity of the TCO. When the TCO is the sole conductive layer of the front electrode, such adverse affects can be highly detrimental.

Further, the efficiency of a solar cell may be increased by texturing the TCO. However, this is often done by etching. In certain example embodiments, etching may be detrimental to the overall solar cell.

Thus, it will be appreciated that there is a need in the art for improved solar cell devices, and/or methods of making the same.

Certain example embodiments of this invention relate to a method of making a solar cell. A layer comprising zinc oxide is sputter-deposited on a glass substrate. The layer comprising zinc oxide is etched with at least a double-agent etchant comprising at least two acids in order to texture a surface of the layer comprising zinc oxide and in order to produce at least first and second feature types having different respective feature sizes. A first semiconductor layer comprising amorphous silicon is formed, directly or indirectly, on the layer comprising zinc oxide. A second semiconductor layer comprising micro-crystalline silicon is formed over and contacting the first semiconductor layer in making the solar cell.

Certain example embodiments of this invention relate to a method of making a solar cell. A layer comprising a transparent conductive oxide (TCO) disposed on a glass substrate is etched with an etchant comprising at least two acids in order to texture a surface of the TCO-based layer. A first semiconductor layer comprising amorphous silicon is formed, directly or indirectly, on the TCO-based layer. A second semiconductor layer comprising micro-crystalline is formed over and contacting the layer comprising amorphous silicon in making the solar cell. The surface of the layer comprising the TCO, post-etching, includes at least first and second feature types, the first feature type being sized so as to scatter light in a first range corresponding to the first semiconductor layer and the second feature type being sized so as to scatter light in a second range corresponding to the second semiconductor layer.

Certain example embodiments of this invention relate to a solar cell, including a glass substrate; a textured transparent conductive oxide (TCO)-based layer comprising zinc oxide; a first semiconductor layer comprising amorphous silicon; and a second semiconductor layer comprising micro-crystalline silicon. The surface of the textured TCO-based layer includes at least first and second feature types, the first feature type being sized so as to scatter light in a first range corresponding to the first semiconductor layer and the second feature type being sized so as to scatter light in a second range corresponding to the second semiconductor layer.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a cross-sectional view of an example photovoltaic device according to certain example embodiments of this invention;

FIG. 2 is an example XRD graph showing AZO with and without an ITO underlayer;

FIG. 3 is a first example layer stack for producing high haze in connection with a textured stoichiometric AZO layer deposited on an ITO layer in accordance with an example embodiment of this invention;

FIG. 4 is a second example layer stack for producing high haze in connection with a textured stoichiometric AZO layer deposited on an ITO layer in accordance with an example embodiment of this invention;

FIG. 5 is a third example layer stack for producing high haze in connection with a textured stoichiometric AZO layer deposited on an ITO layer in accordance with an example embodiment of this invention;

FIG. 6 is cross-sectional view of an AZO-based layer in a solar cell that has been over-etched;

FIG. 7 is cross-sectional view of a semiconductor layer being in direct contact with a metallic, conductive layer due to over-etching;

FIG. 8 is an example layer stack for reducing the possibility of over-etching with a textured stoichiometric AZO layer deposited on an ITO layer in accordance with an example embodiment of this invention;

FIG. 9 is a flowchart showing an exemplary method for making a photovoltaic device including an etch-blocking layer according to certain example embodiments of the invention;

FIG. 10 is a cross-sectional view of an example micro-morph solar cell;

FIG. 11 is a cross-sectional view of an example micro-morph Si based photovoltaic device according to certain example embodiments of this invention; and

FIGS. 12a-b compare AFM and SEM images where single-agent and double-agent etchants were used to texture the surface of magnetron-sputtered ZnO:Al, respectively.

### DETAILED DESCRIPTION OF EXAMPLE EMBODIMENTS OF THE INVENTION

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, single or tandem thin-film solar cells, CdS and/or CdTe (including CdS/CdTe) photovoltaic devices, polysilicon and/or microcrystalline Si photovoltaic devices, and the like.

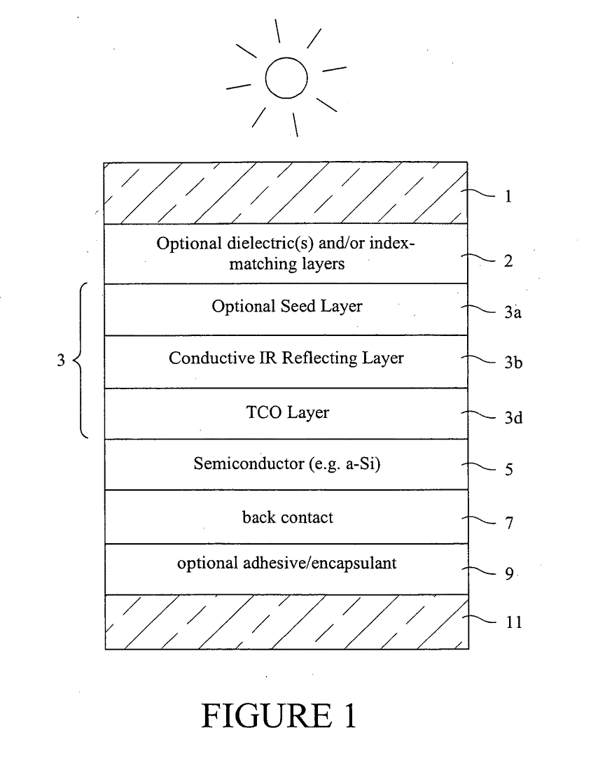

FIG. 1 is a cross sectional view of a photovoltaic device according to an example embodiment of this invention. The photovoltaic device includes transparent front glass substrate 1 (other suitable material may also be used for the substrate instead of glass in certain instances), optional dielectric layer(s) 2, multilayer front electrode 3, active semiconductor film 5 of or including one or more semiconductor layers (such as pin, pn, pinpin tandem layer stacks, or the like), back electrode/contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may also be provided in the device. Front glass substrate 1 and/or rear superstrate (substrate) 11 may be made of soda-lime-silica based glass in certain example embodiments of this invention; and it may have low iron content and/or an antireflection coating thereon to optimize transmission in certain example instances. While substrates 1, 11 may be of glass in certain example embodiments of this invention, other materials such as quartz, plastics or the like may instead be used for substrate(s) 1 and/or 11. Moreover, superstrate 11 is optional in certain instances. Glass 1 and/or 11 may or may not be thermally tempered and/or patterned in certain example embodiments of this invention. Additionally, it will be appreciated that the word “on” as used herein covers both a layer being directly on and indirectly on something, with other layers possibly being located therebetween.

Dielectric layer(s) 2 may be of any substantially transparent material such as a metal oxide and/or nitride which has a refractive index of from about 1.5 to 2.5, more preferably from about 1.6 to 2.5, more preferably from about 1.6 to 2.2, more preferably from about 1.6 to 2.0, and most preferably from about 1.6 to 1.8. However, in certain situations, the dielectric layer 2 may have a refractive index (n) of from about 2.3 to 2.5. Example materials for dielectric layer 2 include silicon oxide, silicon nitride, silicon oxynitride, zinc oxide, tin oxide, titanium oxide (e.g., TiO₂), aluminum oxynitride, aluminum oxide, or mixtures thereof. Dielectric layer(s) 2 functions as a barrier layer in certain example embodiments of this invention, to reduce materials such as sodium from migrating outwardly from the glass substrate 1 and reaching the IR reflecting layer(s) and/or semiconductor. Moreover, dielectric layer 2 is material having a refractive index (n) in the range discussed above, in order to reduce visible light reflection and thus increase transmission of visible light (e.g., light from about 450-700 nm and/or 450-600 nm) through the coating and into the semiconductor 5 which leads to increased photovoltaic module output power.

Still referring to FIG. 1, multilayer front electrode 3 in the example embodiment shown in FIG. 1, which is provided for purposes of example only and is not intended to be limiting, includes from the glass substrate 1 outwardly a first optional seed layer 3a, conductive, substantially metallic, substantially transparent IR reflecting layer 3b, transparent conductive oxide layer 3d, and optional buffer layer 3f. Layer 3a is optional and may be a dielectric layer and/or may serve as a seed layer for the layer 3b. In certain example embodiments, however, layer 3a may be part of the dielectric/optically-matching layer(s) 2. This multilayer film 3 makes up the front electrode in certain example embodiments of this invention. Of course, it is possible for certain layers of electrode 3 to be removed in certain alternative embodiments of this invention, and it is also possible for additional layers to be provided in the multilayer electrode 3. Front electrode 3 may be continuous across all or a substantial portion of glass substrate 1, or alternatively may be patterned into a desired design (e.g., stripes), in different example embodiments of this invention. Each of layers/films 1-3 is substantially transparent in certain example embodiments of this invention.

Conductive substantially metallic IR reflecting layer 3b may be of or based on any suitable IR reflecting material such as silver, gold, or the like. These materials reflect significant amounts of IR radiation, thereby reducing the amount of IR which reaches the semiconductor film 5. Since IR increases the temperature of the device, the reduction of the amount of IR radiation reaching the semiconductor film 5 sometimes may be advantageous in that it may reduce the operating temperature of the photovoltaic module so as to increase module output power. Moreover, the highly conductive nature of substantially metallic layer 3b permits the conductivity of the overall electrode 3 to be increased. In certain example embodiments of this invention, the multilayer electrode 3 has a sheet resistance of less than or equal to about 12 ohms/square, more preferably less than or equal to about 9 ohms/square, and even more preferably less than or equal to about 6 ohms/square. Again, the increased conductivity (same as reduced sheet resistance) increases the overall photovoltaic module output power, by reducing resistive losses in the lateral direction in which current flows to be collected at the edge of cell segments. It is noted that conductive substantially metallic IR reflecting layer 3b (as well as the other layers of the electrode 3) is thin enough so as to be substantially transparent to visible light. In certain example embodiments of this invention, conductive substantially metallic IR reflecting layer 3b may be from about 3 to 18 nm thick, more preferably from about 5 to 12 nm thick, and most preferably from about 6 to 11 nm thick in certain example embodiments of this invention. These thicknesses are desirable in that they permit the layer 3b to reflect significant amounts of IR radiation, while at the same time being substantially transparent to visible radiation which is permitted to reach the semiconductor 5 to be transformed by the photovoltaic device into electrical energy. The highly conductive IR reflecting layer 3b attribute to the overall conductivity of the electrode 3 much more than the TCO layers; this allows for expansion of the process window(s) of the TCO layer(s) which has a limited window area to achieve both high conductivity and transparency.

TCO layer 3d may be of any suitable TCO material including but not limited to conducive forms of zinc oxide, zinc aluminum oxide, tin oxide, indium-tin-oxide, indium zinc oxide (which may or may not be doped with silver), or the like. These layers are typically substoichiometric so as to render them conductive as is known in the art. For example, these layers are made of material(s) which gives them a resistance of no more than about 10 ohm-cm (more preferably no more than about 1 ohm-cm, and most preferably no more than about 20 mohm-cm). One or more of these layers may be doped with other materials such as fluorine, aluminum, antimony or the like in certain example instances, so long as they remain conductive and substantially transparent to visible light. In certain example embodiments of this invention, TCO layer 3d is from about 3 to 80 nm thick, more preferably from about 5-30 nm thick, with an example thickness being about 10 nm. Optional layer 3a is provided mainly as a seeding layer for layer 3b and/or for antireflection purposes, and its conductivity is not as important as that of layers 3b-3e (thus, layer 3a may be a dielectric in certain example embodiments). In other example embodiments of this invention, TCO layer 3d is from about 20 to 150 nm thick, more preferably from about 40 to 120 nm thick, with an example thickness being about 74-75 nm. In still further example embodiments of this invention, TCO layer 3d is from about 20 to 180 nm thick, more preferably from about 40 to 130 nm thick, with an example thickness being about 94 or 115 nm. In certain example embodiments, part of layer 3d, e.g., from about 1-25 nm or 5-25 nm thick portion, at the interface between layers 3d and 5 may be replaced with a low conductivity high refractive index (n) film 3f such as titanium oxide to enhance transmission of light as well as to reduce back diffusion of generated electrical carriers; in this way performance may be further improved. In certain example embodiments, more than one of each of substantially metallic layer 3b and TCO-based layer 3d may be included in the front electrode of a photovoltaic device, in an alternating fashion (e.g., 3b/3d/3b/3d etc.).

In certain example embodiments of this invention, the photovoltaic device may be made by providing glass substrate 1, and then depositing (e.g., via sputtering or any other suitable technique) an optional dielectric and/or index-matching layer and/or coating on the glass substrate. Then, multilayer electrode 3 is deposited on the substrate 1. Thereafter the structure including substrate 1 and front electrode 3 is coupled with the rest of the device in order to form the photovoltaic device shown in FIG. 1. For example, the semiconductor layer 5 may then be formed over the front electrode on substrate 1. Alternatively, the back contact 7 and semiconductor 5 may be fabricated/formed on substrate 11 (e.g., of glass or other suitable material) first; then the electrode 3 and dielectric 2 may be formed on semiconductor 5 and encapsulated by the substrate 1 via an adhesive such as EVA.

In certain example embodiments, when TCO layer(s) and conductive substantially metallic IR reflecting layers are alternated, the alternating nature of the TCO layers 3d and the conductive substantially metallic IR reflecting layers 3b, is also advantageous in that it also one, two, three, four or all of the following advantages to be realized: (a) reduced sheet resistance (Rs) of the overall electrode 3 and thus increased conductivity and improved overall photovoltaic module output power; (b) increased reflection of infrared (IR) radiation by the electrode 3 thereby reducing the operating temperature of the semiconductor 5 portion of the photovoltaic module so as to increase module output power; (c) reduced reflection and increased transmission of light in the visible region of from about 450-700 nm (and/or 450-600 nm) by the front electrode 3 which leads to increased photovoltaic module output power; (d) reduced total thickness of the front electrode coating 3 which can reduce fabrication costs and/or time; and/or (e) an improved or enlarged process window in forming the TCO layer(s) because of the reduced impact of the TCO's conductivity on the overall electric properties of the module given the presence of the highly conductive substantially metallic layer(s).

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe may also be used for semiconductor film 5 in alternative embodiments of this invention.

Back contact, reflector and/or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA or PVB. However, other materials such as Tedlar type plastic, Nuvasil type plastic, Tefzel type plastic or the like may instead be used for layer 9 in different instances.

Given the structure identified above, certain example embodiments relate to a front transparent conductive electrode for solar cell devices (e.g., amorphous silicon or a-Si solar cell devices), and/or methods of making the same. Certain example embodiments enable advantageously enable high haze to be realized in the top layer of the thin film stack.

The front transparent contact of a typical superstrate thin film amorphous silicon (a-Si) solar cell includes a glass base supporting a transparent conductive film. As indicated above, this transparent conductive film typically includes pyrolytically deposited fluorine-doped tin oxide (SnO₂:F). The efficiency of a-Si modules sometimes may be increased by 20% via surface texturing of the transparent conductor on which the a-Si semiconductor is deposited for the effective light scattering into the semiconductor layer of the device. The pyrolytically deposited SnO₂:F typically is “naturally” textured during its deposition.

Sputter-deposited aluminum-doped zinc oxide (AZO) may be used as an alternative to pyrolytically deposited SnO₂:F. The AZO may be chemically etched following its deposition. The etching process may create sufficient roughness of the AZO surface to produce the needed light scattering. Unfortunately, however, the chemical etching often results in a substantial thickness loss of the AZO layer. This generally requires depositing a relatively thick (e.g., about 1 micron thick) sputter-deposited AZO layer to provide a sufficiently low sheet resistance. As will be appreciated, the low sheet resistance of the transparent contact is needed for the effective extraction of electrical charges generated in the device.

An alternative technique for achieving a sufficient lateral conductivity of the textured transparent contact is to deposit an additional highly conductive transparent layer such as, for example, indium tin oxide (ITO), below the AZO. In such a case, the AZO deposited on the ITO film may be made substantially thinner. This technique may offer certain advantages over a single layer AZO design, e.g., when the deposition (of some or all layers) is performed without intentional heating of the substrate (and/or the layers thereon). In other words, this technique may offer certain advantages over a single layer AZO design when the deposition is performed approximately at room temperature, thereby resulting in RT-AZO. The stack may require post-deposition baking (e.g., at about 300-500 degrees C.) to reduce optical absorption and electrical resistivity of the transparent electrode.

To achieve the desired optical and electrical performance of sputtered RT-AZO, the use of near-stoichiometric ceramic AZO targets may be desirable. For example, using close-to-stoichiometric ceramic AZO targets may make it easier to optimize the composition of the RT-AZO deposit film by incorporating oxygen during the post-deposition baking. One disadvantage of using stoichiometric targets for the AZO deposition on ITO is that the crystalline ITO has a tendency to inhibit haze in stoichiometric AZO during texturing. This also applies to high-temperature AZO (HT-AZO) deposited on the ITO layer.

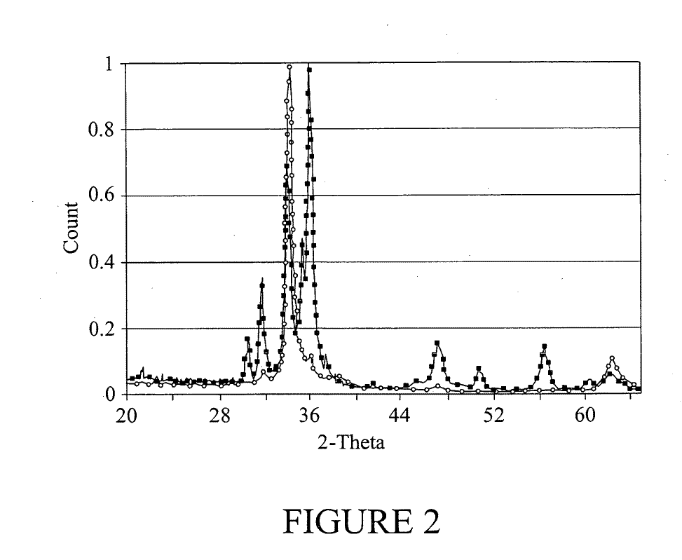

One reason that the ITO layer affects haze development in AZO relates to the fact that the ability of the AZO layer to produce haze depends on the ratio of strain in the film in the directions parallel and perpendicular to its growth axis. In AZO deposited on an amorphous substrate, this ratio is sufficient to result in a high haze. The presence of the crystalline ITO layer, however, affects the crystallinity of the AZO and results in the reduced strain ratio. This, in turn, results in a reduced difference of the etch rate in the two orthogonal directions of the crystalline AZO and, ultimately, in a low haze. FIG. 2 is an example XRD graph showing AZO with (solid squares) and without (hollow circles) an ITO underlayer.

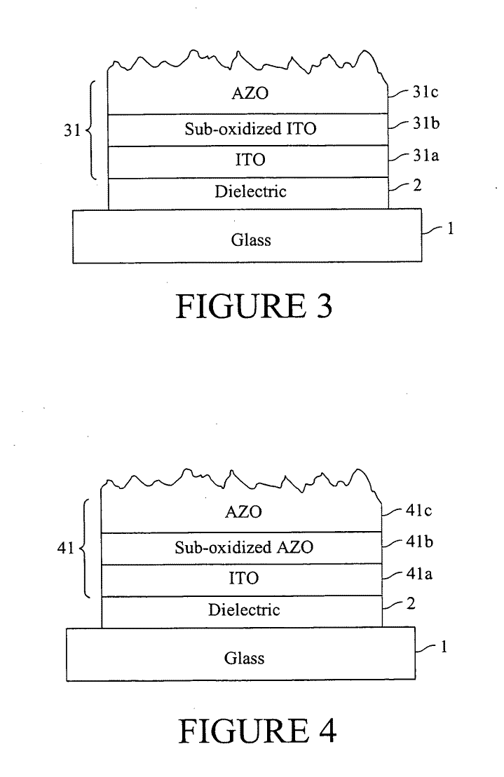

Certain example embodiments therefore relate to techniques that produce high haze in textured stoichiometric AZO deposited on an ITO film. This may be accomplished using one or more of the following and/or other example techniques. The resulting layer stacks are shown in FIGS. 3-5 (described in greater detail below). In brief, FIGS. 3-5 each show approaches for producing high haze in connection with a textured stoichiometric AZO layer deposited (directly or indirectly) on an ITO layer in accordance with example embodiments of this invention.

First, a substantially sub-oxidized AZO layer may be provided between the ITO layer and the stoichiometric AZO layer. This example technique may result in an “amorphization” of the lower portion of the AZO layer and/or the upper portion of the ITO layer. This tends to reduce (and sometimes even cancel out) the effect of the crystalline ITO on the AZO layer.

This first illustrative arrangement is shown, for example, in FIG. 3. The FIG. 3 example embodiment includes a glass substrate 1, which supports a dielectric layer 2 and a multilayer transparent conductive coating (TCC) 31. The underlying dielectric layer 2 supports the TCC 31, which may comprise (in order moving away from the dielectric layer 2), an ITO layer 31a, a sub-oxidized ITO layer 31b, and a layer of textured AZO 31c. The ITO layer 31a and/or the AZO 31c may be stoichiometric or substantially stoichiometric in different embodiments of this invention. It will be appreciated that the sub-oxidized ITO layer 31b will contain less oxygen than the “main” ITO layer 31a. In certain example embodiments, the “main” ITO layer 31a also may be sub-oxidized. However, even in embodiments where the “main” ITO layer 31a is sub-oxidized, the sub-oxidized ITO layer 31b still will contain less oxygen than the “main” ITO layer 31a. In certain example embodiments, the sub-oxidized ITO layer 31b preferably has an absorption of 3-6% per 100 nm of thickness, more preferably 4.5% per 100 nm of thickness. In certain example embodiments, the sub-oxidized ITO layer 31b may have optical constants n and k of 1.9-2.05 and 0.005-0.025, respectively, at 550 nm, and more preferably 1.97 and 0.01, respectively at 550 nm.

In certain example embodiments, the ITO layer 31a and/or the AZO 31c may have a refractive index of about 1.9-2.05 at 550 nm. In certain example embodiments, the ITO layer 31a may be provided at a thickness of 50-500 nm, more preferably 100-300 nm, and still more preferably at about 200 nm. In certain example embodiments, the AZO 31c may be provided at a thickness of 300-1000 nm, more preferably 400-700 nm, and still more preferably at about 500 nm. In certain example embodiments, the sub-oxidized ITO layer 31b may be provided at a thickness of 10-200 nm, more preferably 20-100 nm, and still more preferably at about 40 nm.

A conductive layer of or comprising Ag (not shown in FIG. 3) may be deposited above and/or below the ITO layer 31a in certain example embodiments. This Ag-based layer may be highly conductive and may be deposited to a thickness of 0.5-3 nm, more preferably 0.7-2 nm, and sometimes to about 1 nm.

In certain example embodiments, rather than providing two separate ITO layers 31a and 31b, a single graded ITO layer (not shown) may be provided, such that the oxygen content is higher closer to the dielectric layer 2 and lower closer to the AZO layer 31c. In certain example embodiments, even when separate ITO layers 31a and 31b are provided, one or both of such layers may be graded, e.g., as described above. In certain example embodiments AZO etching may be performed using a 5% acetic acid solution.

The sub-oxidized ITO layer 31b, provided as an insertion layer, may help serve as an etch stop. In general, absent the insertion layer comprising sub-oxidized ITO layer 31b, the crystallinity of the underlying “main” ITO layer 31a will affect the growth of the AZO and reduce haze because it tends to inhibit large peak/valley formation. Similar principles apply when a single, graded ITO layer is provided. In certain example embodiments, the crystallinity of the AZO will be changed, creating an enlarged peak-to-valley distance, e.g., by enabling the AZO to form higher peaks and/or lower valleys. In particular, in certain example embodiments, the 002 peak will shift, causing the etch rate in the horizontal vs. vertical directions change together and, for example, producing deeper valleys.

Second, a substantially sub-oxidized ITO layer may be provided between stoichiometric ITO and AZO layers. Like the first example technique, this second example technique also may result in an “amorphization” of the lower portion of the AZO layer and/or the upper portion of the ITO layer, which tends to reduce (and sometimes even cancel out) the effect of the crystalline ITO on the AZO layer.

This second illustrative arrangement is shown, for example, in FIG. 4. The FIG. 4 example embodiment is similar to the FIG. 3 example embodiment in that it includes a glass substrate 1, which supports a dielectric layer 2 and a multilayer transparent conductive coating (TCC) 41. The underlying dielectric layer 2 supports the TCC 41, which may comprise (in order moving away from the dielectric layer 2), an ITO layer 41a, a sub-oxidized AZO layer 41b, and a layer of textured AZO 41c. It will be appreciated that the sub-oxidized AZO layer 41b will contain less oxygen than the “main” AZO layer 41c. In certain example embodiments, the “main” AZO layer 41c also may be sub-oxidized. However, even in embodiments where the “main” AZO layer 41c is sub-oxidized, the sub-oxidized AZO layer 41b still will contain less oxygen than the “main” AZO layer 41c.

The sub-oxidized AZO layer 41b in certain example embodiments preferably has an absorption of 2-8% per 100 nm of thickness, and sometimes around 5.3% per 100 nm of thickness. The thickness of the sub-oxidized AZO layer 41b in certain example embodiments is 10-200 nm, more preferably 20-100 nm, and sometimes is preferably about 40 nm. In certain example embodiments, the sub-oxidized AZO layer 41b may have optical constants n and k of 1.93 and 0.008, respectively, at 550 nm.

In certain example embodiments, rather than providing two separate AZO layers 31b and 31c, a single graded AZO layer (not shown) may be provided, such that the oxygen content is higher farther from the substrate 1 and lower closer to the substrate 1. In certain example embodiments, even when separate AZO layers 41b and 41c are provided, one or both of such layers may be graded, e.g., as described above.

Similar to the above, the sub-oxidized AZO layer 31b, provided as an insertion layer, may help serve as an etch stop and may help reduce the effects of the underlying ITO's crystallinity. Also, similar principles apply when a single, graded AZO layer is provided.

In certain example embodiments, an over-oxidized layer may be introduced adjacent to the sub-oxided insertion layer. For instance, in the FIG. 3 example embodiment, an over-oxidized ITO layer may be provided adjacent to the sub-oxided insertion layer 31b. Similarly, in the FIG. 4 example embodiment, an over-oxidized AZO layer may be provided adjacent to the sub-oxided insertion layer 41b. In certain example embodiments, the optional over-oxidized layer may be used as an internal source of oxygen during post-deposition baking. This may help “bake out” the optical absorption of the sub-oxided insertion layer after it has served its role in helping to form the AZO able to provide high haze. The optical absorption of such a layer may be from 1-3% (integrated over 400-700 nm wavelength range, for example) in certain example embodiments. The over-oxided layer may be about 20-100 nm thick, more preferably 40 nm thick, in certain example embodiments. In certain example embodiments, the over-oxided layer may be provided below the sub-oxided insertion layer. A temporary over-oxided layer also may be provided in embodiments where graded layers are used in accordance with certain example embodiments.

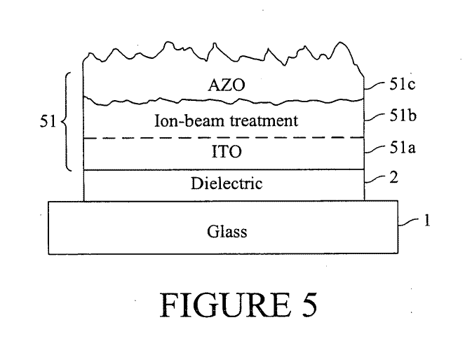

Third, the ITO may be ion-beam treated before providing the top AZO layer. The harsh ion beam treatment of this technique may be used to at least partially erode the upper portion of the ITO so that the AZO layer is not as affected by the ITO crystallinity. This illustrative arrangement is shown, for example, in FIG. 5. The FIG. 5 example embodiment includes a glass substrate 1, which supports a dielectric layer 2 and a multi-layer TCC 51. The multi-layer TCC includes an ITO layer 51a that has been ion-beam treated in the region 51b. The ion-beam treatment in the region 51b affects the crystallinity of at least a portion of the deposited ITO which, in turn, enables the AZO layer 51c to grow and form peaks and valleys as described above.

The ion beam may be implemented at the end of the ITO layer deposition, and the ion beam may use Ar, O₂, and/or any suitable combination of these and/or other gasses. In general, an ion-beam voltage of greater than about 500 V will sufficiently roughen the ITO surface; however a voltage greater than 1000 V is preferred, and a voltage of 3000 V sometimes may be used.

Ion beams, ion sources, ion beam treatments, and the like are disclosed, for example, U.S. Pat. Nos. 6,808,606; 7,030,390; 7,183,559; 7,198,699; 7,229,533; 7,311,975; 7,405,411; 7,488,951; and 7,563,347, and U.S. Publication Nos. 2005/0082493; 2008/0017112; 2008/0199702, the entire contents of each of which is hereby incorporated herein by reference.

In other example embodiments, an alternate method of making a solar cell and/or an alternate structure for the front electrode of a solar cell is/are provided.

In certain example embodiments, it may be desirable to provide a front electrode having only one transparent conductive oxide-based layer and only one conductive, substantially metallic IR reflecting layer. However, if the TCO layer is not rough enough as-deposited, the surface portion (e.g., starting at the surface and extending into the depth of the layer) of the TCO layer may be etched in order to texture its surface therefore increasing the efficiency of the solar cell in certain cases. Etching and/or texturing of the TCO layer is sometimes performed by using a weak acid. However, in certain instances, the TCO layer may not be sufficiently resistant to etching from the weak acid. In certain example embodiments, “weak” spots in the TCO layer may result in random portions of the layer being etched away substantially. In certain cases, the etching of these weak points may be so extensive that the layer under the TCO layer (e.g., the conductive, substantially metallic layer) may be nearly, partially, and/or completely exposed at these certain random points.

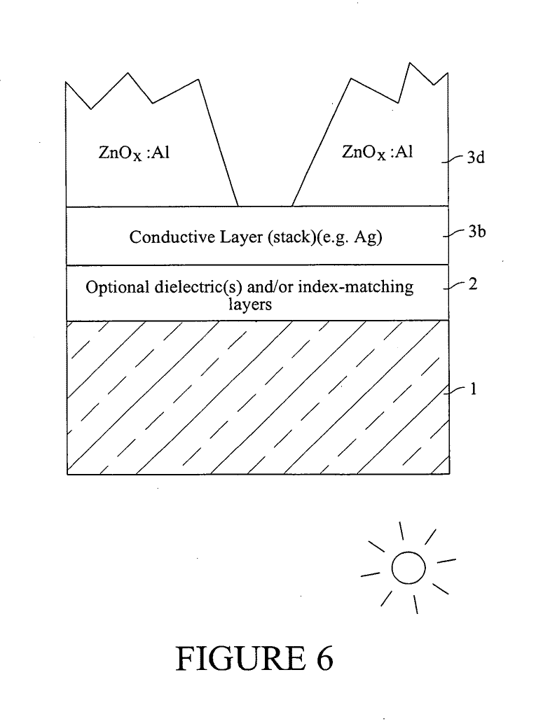

This phenomenon is illustrated in FIG. 6. FIG. 6 is a cross-section view of a portion of a photovoltaic device. FIG. 6 includes substrate 1, upon which (moving outwardly from the substrate) index-matching layer(s) 2, and an electrode comprising a thin, substantially transparent conductive layer and/or layer stack 3b and a transparent conductive oxide layer 3d, are deposited.

In certain other example embodiments, a transparent conductive contact and/or front electrode may comprise a textured Al-doped ZnOx (AZO) top layer (layer 3d) and a thin, substantially transparent conductive under-layer 3b (e.g., a silver-based under-layer). In other example embodiments, conductive layer (stack) 3b may further comprise a NiCrOx “cap” on one or both sides of the thin, substantially transparent conductive layer in order to increase the lateral conductivity (not shown). However, this NiCrOx cap is optional and is only used in some instances on one or both sides of conductive layer 3b.

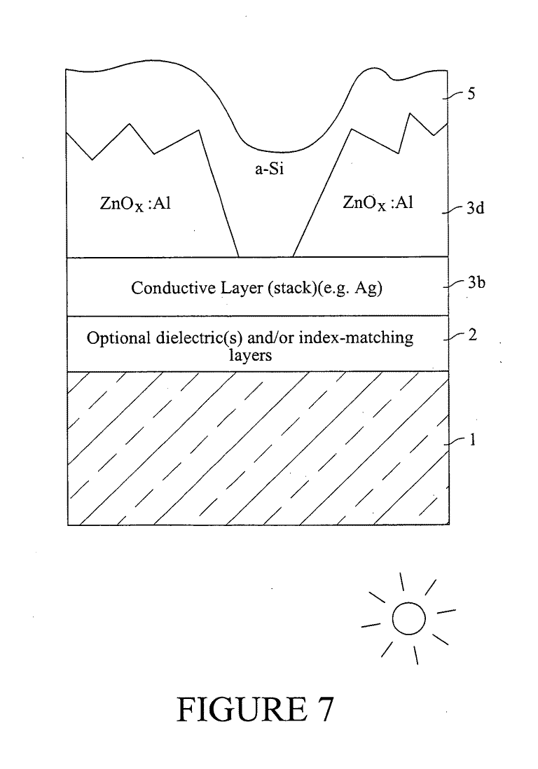

In certain example embodiments, when a TCO-based layer such as AZO is used, the layer may not be sufficiently rough as-deposited, and therefore texturing through the use of a weak acid (e.g., diluted acetic acid, hydrochloric acid, and the like) may be desirable. However, particularly when AZO is used as the TCO layer, the weak spots as described above may be present in the AZO layer. Again, these weak spots may result in over-etching of certain portions of the coating (the points where over-etching may occur may be random in certain embodiments). In certain cases, the over-etching may reach the substantially transparent conductive layer 3b located below the textured TCO 3d. In those cases, when semiconductor 5 is deposited over the textured TCO 3d (as illustrated in FIG. 7), the semiconductor 5 may be in close proximity to and/or direct contact with conductive layer 3b.

Such proximity and/or direct contact between layers 3b and 5, as illustrated in FIG. 7, may be undesirable in that it may result in an abrupt transition from a low refractive index conductive layer (e.g., a layer based on silver) to a high refractive index semiconductor (e.g., Si) in random spots of the coating, in certain cases. Another problem that may arise in certain example embodiments is that an Si-based semiconductor may be in direct electric contact with the highly conductive silver-based (for example) layer. Contacts such as these described herein between layers 3b and 5 may be undesirable in certain example embodiments.

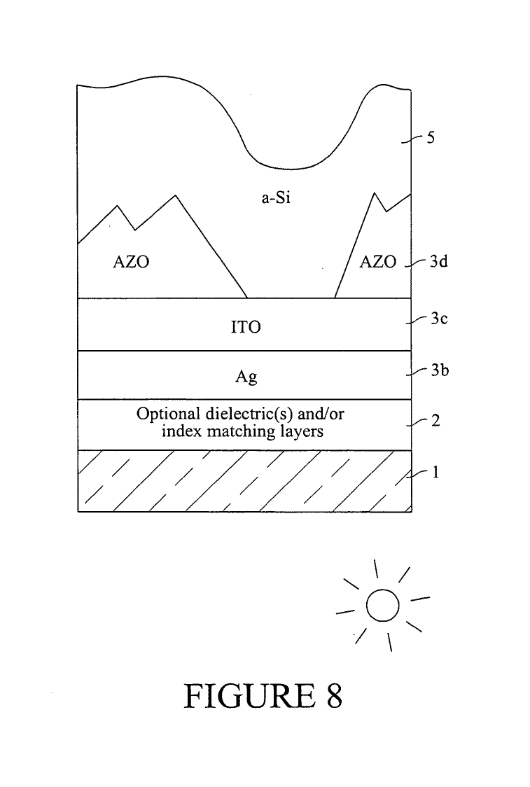

It has advantageously been found that the formation of undesirable contacts between conductive layer 3b and semiconductor 5 through “over-etched” spots of textured TCO layer 3d may be reduced by inserting a thin blocking layer 3c in between conductive layer 3b and TCO layer 3d. This is illustrated in FIG. 8. In certain example embodiments, the blocking layer 3c may comprise any material that is highly conductive and has a poor etchability for many weak acids. For example, in certain exemplary embodiments, blocking layer 3c may be of or include indium tin oxide (ITO). Blocking layer 3c may have a thickness of from about 1 to 300 nm, more preferably from about 2 to 200 nm.

In certain example embodiments, layer 3c advantageously may be of or include a material that is more resistant to etching by weak acids (e.g., 3c should be of a material that has a poor etchability for many weak acids), e.g., as compared to the layer to be roughened 3d by the etchant. Examples of weak acids include, for instance, acetic acid, diluted acetic acid, various concentrations of hydrochloric acid (HCl), and the like. Of course, other acid etchants may be used in different example implementations. In certain instances, the weak acid may be any acid having a pH of from about 1 to 6, more preferably from about 2 to 5, and most preferably from about 2.5 to 4.5.

Further, layer 3c may be conductive and/or highly conductive in certain example embodiments, in order to increase the conductivity and other properties of the overall electrode and/or solar cell. Moreover, in other example embodiments, layers 3b, 3c, and 3d may be repeated at least once (e.g. such that electrode 3 comprises layer 3b/3c/3d/3b/3c/3d.

FIG. 8 also helps illustrate that, through the provision of layer 3c, which is a transparent conductive oxide-based layer that is more resistant to etching by weak acids than is layer 3d in certain example embodiments, a barrier is created (e.g., via blocking layer 3c) between the TCO layer 3d being etched and the substantially transparent conductive layer 3b. In certain example embodiments, layer 3c will reduce (and sometimes even completely prevent) over-etching of TCO layer 3d related to the application of the weak acid. The inclusion of etching-blocking layer 3c between TCO layer 3d and the conductive substantially metallic IR reflecting layer 3b, may sometimes also be considered advantageous in that it can reduce (and sometimes even prevent), direct contact between conductive layer 3b and semiconductor 5. Such contact is undesirable in that it may decrease the efficiency and/or performance of the solar cell due to abrupt changes in refractive index and/or substantially direct electrical contact between the semiconductor and the relatively highly conductive layer 3b (e.g., a silver-based layer). In other example embodiments, where a capping layer is provided above and/or below conductive layer 3b, contact that arises due to over-etching of the TCO-based layer may be between the capping layer and the semiconductor. In certain example embodiments, contact between the semiconductor and the thin capping layer is also disadvantageous.

In certain example embodiments, blocking layer 3c may advantageously be of or include indium tin oxide (e.g., ITO). ITO has sufficient etch-stop properties that render it more resistant to weak acids than AZO. When blocking layer 3c comprises a transparent conductive oxide (such as ITO), the overall conductivity, transmission, and other properties of the electrode may remain substantially unaffected or even improved. Furthermore, when TCO layer 3d comprises AZO, and blocking layer 3c comprises ITO, it may be particularly advantageous because the overall conductivity of the electrode may be improved in some instances.

Although the example design shown in and described in connection with FIG. 8 may not completely eliminate all possibilities for the over-etching of layer 3d (particularly when it is based on ZnOₓ:Al), including a blocking layer 3c that is more resistant to weak acids (e.g., based on ITO) may reduce the risk of, and sometimes even prevent, direct contact with the conductive layer 3b (and/or any capping layers provided above or below conductive layer 3b). In certain example embodiments, it is particularly advantageous for the TCO-based layer 3d to be of or include aluminum-doped zinc oxide, and for blocking layer 3c to be based on ITO. In some instances, ITO and AZO may have similar optical constants. This is advantageous in that there will be sufficient optical separation between the conductive layer 3b and any textured layers (e.g., layer 3d). For instance, in certain example embodiments, the selection of ITO and AZO also may be advantageous in the sense that they may be deposited so as to have closely matching optical constants n and k, preferably within about 15% of one another, more preferably within about 10% of one another, and sometimes within 5% or less of one another. Further, including a layer based on ITO in the front electrode may also increase the overall conductivity of the front electrode and/or front contact.

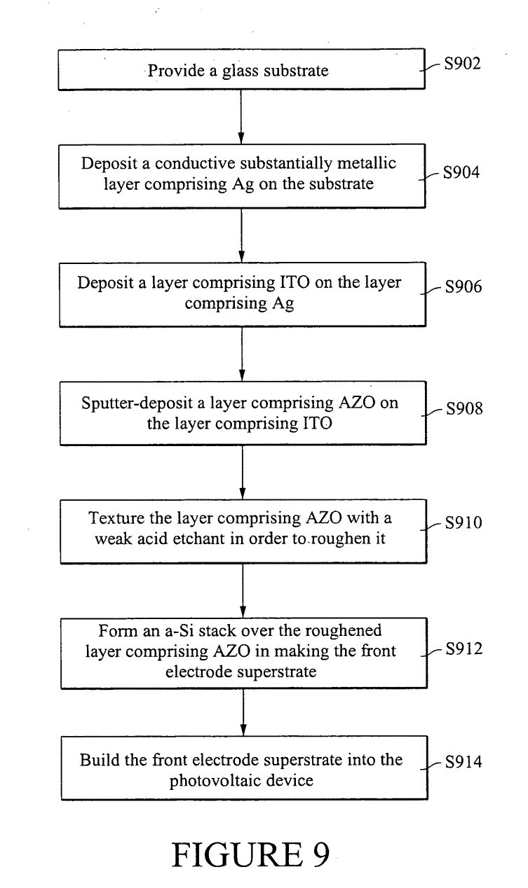

FIG. 9 is a flowchart illustrating an example process for making a textured front contact comprising at least a TCO layer based on AZO deposited over a conductive layer (and/or conductive layer stack), with a blocking layer based on ITO located therebetween in accordance with certain example embodiments of this invention. A glass substrate 1 that serves as the superstrate for the front electrode is provided (step S902). A layer comprising a conductive, substantially metallic material such as silver (3b) is then deposited directly or indirectly on the substrate 1 (step S904). A layer comprising ITO 3c is then deposited directly or indirectly on the layer of silver 3b (step S906). A layer comprising AZO 3d is then sputter-deposited directly or indirectly on the ITO (step S908). This layer comprising AZO 3d is then textured with a weak acid (step S910), e.g., to roughen its surface (potentially improving haze and the overall performance of the photovoltaic device in which the superstrate is to be installed). An a-Si or other suitable semiconductor stack 5 is formed atop the textured layer comprising sputtered AZO 3d (step S912) in making the front electrode superstrate. This front electrode superstrate may then be built into the photovoltaic device (step S914) in certain example embodiments. Although not shown in FIG. 9, additional layers may be provided including, for example, index match or dielectric layers, adhesive layers, sub-oxidized ITO and/or AZO layers, etc.

In certain example embodiments, some or all of the layers may be sputter-deposited. Of course, some or all of the layers may be deposited by other techniques such as, for example, wet-chemical techniques, pyrolytic techniques, CVD, and/or the like.

In certain example embodiments, the dielectric layer(s) 2 may be a single layer or a multi-layer stack. In further example embodiments, layer 2 may be a single or multi-layer stack comprising optical and/or index matching layers. These layers may help to reduce reflection in certain example embodiments. The dielectric layer or dielectric layer stack 2 may be provided directly on the glass substrate. For example, in certain example embodiments, the dielectric layer 2 may comprise titanium oxide, silicon oxide, silicon nitride, silicon oxynitride, zirconium oxide, and/or the like. Indeed, any transparent or partially transparent dielectric layer may be used in different example embodiments of this invention, alone or in a layer stack with the same or different dielectric layers. If a titanium oxide layer is provided, it may in certain example embodiments have a thickness of 0-30 nm, more preferably 5-20 nm, and still more preferably about 7 nm. If a silicon oxynitride layer is provided, it may in certain example embodiments have a refractive index of 1.5-1.9 or, more preferably, of about 1.6. Furthermore, if a silicon oxynitride layer is provided, it may in certain example embodiments have a thickness of 0-80 nm, more preferably 10-50 nm, and still more preferably about 30 nm.

Although certain example embodiments have been described as having a layer of AZO, other transparent conductive coatings may be used in place of or in addition to the AZO. For example, transparent conductive oxide (TCO) coatings such as ITO, indium gallium zinc oxide, indium gallium oxide, indium zinc oxide and/or combinations thereof may be used in place of, or in addition to, the AZO.

In certain example embodiments, the entire contact assembly may be post-deposition baked and/or heat treated. Such baking and/or heat treating in certain example embodiments may be performed at a temperature of 200-550 degrees C., more preferably about 400 degrees C. The baking and/or heat treating may be performed in certain example embodiments for 1-30 minutes, more preferably 10-30 minutes. Such baking and/or heat treating advantageously may help increase transmission and conductivity, e.g., by making some or all of the layers more crystallized. Baking and/or heat treating may be performed before or after the etching, in different embodiments of this invention.

In certain example embodiments, the AZO layer may have a haze from 5-95%, more preferably at least about 40%.

Any suitable semiconductor may be used in connection with different embodiments of this invention. For example, certain example embodiments may incorporate an a-Si single-junction solar cell, an a-Si tandem junction solar cell, and/or the like. As alluded to above, the insertion layers and/or the roughening via ion-beam treatment advantageously may help serve as an etch stop, reducing the likelihood that craters produced during etching will go all of the way through the AZO layer and form shorts. The incorporation of the insertion layers and/or the roughening via ion-beam treatment advantageously also may help overcome optical mismatch problems as between the various layers in the overall solar cell.

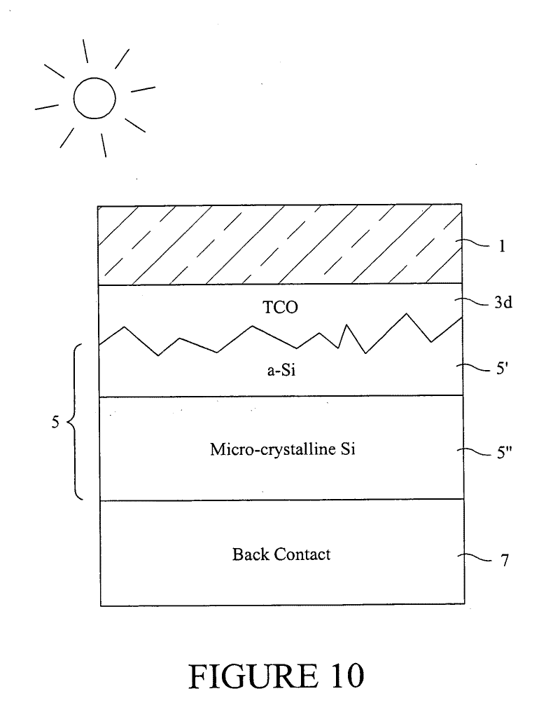

As indicated above, certain example embodiments of this invention incorporate micro-morph silicon semiconductors. Micro-morph solar cells may comprise a semiconductor including at least two portions and/or layers. FIG. 10 is an example micro-morph solar cell. FIG. 10 is similar to an a-Si (amorphous silicon) solar cell, except that there are both an amorphous silicon-based layer and a micro-crystalline silicon-based layer. Together, in certain example embodiments, these layers serve as the semiconductor for the solar cell.

More specifically, FIG. 10 depicts front (light incident) glass substrate/superstrate 1, TCO-based layer 3d, semiconductor 5, which includes amorphous silicon (a-Si) layer/portion 5′ and micro-crystalline layer/portion 5″, and back contact 7. The a-Si and micro-crystalline aspects of the semiconductor may be separate and distinct layers, or portions of the same layer, in different example embodiments. The specific composition of elements 1, 3d, and 7 may be as described above.

Accordingly, in certain example according to this invention, micro-morph silicon solar cells include at least two silicon layers (e.g., layers or portions)—amorphous silicon 5′ and micro-crystalline silicon 5″—combined in one layer stack, to provide an efficient absorption of solar light.

In certain example embodiments, it may be advantageous to provide a textured transparent conductive oxide layer 3d on the light incident side of a semiconductor 5, e.g., in order to help increase the absorption of light in the semiconductor, in turn improving the overall efficiency of the cell. This is also the case with micro-morph solar cells.

In certain example embodiments, light in the range of up to about 1.2 micron may efficiently scattered by texturing certain layers, e.g., to form features of comparable sizes. It is also desirable to increase the absorption of the long-wave component (up to 1.2 micron) of solar light by the micro-crystalline portion of the device.

Pyrolytic fluorine-doped tin oxide is available as a textured TCO for light scattering. The pyramidal shape of the surface features of textured fluorine-doped tin oxide may, however, be less than ideal in certain instances, e.g., for the effective long-wave light scattering to shallow angles to the surface of the coating. By contrast, in certain cases, craters formed during ZnO:Al (e.g., AZO) etching in a highly-diluted acid (for example, HCl) may have a shape that provides for advantageous light scattering.

In certain example embodiments, surface craters (e.g., features) may be formed in ZnO:Al-based TCO layers by texturing the TCO surface by placing it in contact with an acid (e.g., diluted acetic acid). The TCO layer(s) may be deposited in a monolithic configuration and/or on a thin metal-based transparent conductive coating (TCC), according to different example embodiments.

With sputtered ZnO:Al, acid texturing may result in the formation of one size of the surface features, in certain example embodiments. In certain cases, these surface features may be on the scale of several hundred nanometers. One size of surface features may result in the effective scattering of only one spectral region of the solar light. However, each layer/portion of the semiconductor in a micro-morph solar cell may absorb light best at different wavelengths of light. Thus, in certain instances, it will be appreciated that only one surface feature size may result in lower micro-morph solar cell efficiency compared to what would result from a situation where multiple feature sizes are provided.

As explained above, in certain example embodiments semiconductor layer(s) most efficiently absorb differing wavelengths of light, depending on the materials the semiconductor comprises. Thus, in example instances where a solar cell may have only one silicon layer, the TCO-based layer may be textured with craters/features of a particular size. The size of the features of the textured surface of the TCO may be selected and/or controlled such that the selected size enhances the light scattering effect for light of a particular wavelength.

In other words, light at varying wavelengths may scatter particularly well when incident upon different sized features. The character of the textured surface (e.g., the feature size) may be selected and/or controlled so as to enhance the scattering effect of light at a particular wavelength, with the wavelength (and thus feature size) being selected based on the material of the semiconductor.

Accordingly, by selecting and/or controlling the size(s) of the feature(s) of the textured TCO surface, the absorption and efficiency of the solar cell may be improved in certain example embodiments.

As alluded to above, when only one silicon-based layer is present as a semiconductor-type layer 5 in a solar cell, the feature size may be selected based on that layer. However, when two or more layers and/or portions of layers are present, these layers (e.g., 5′ and 5″ in FIG. 10) may not absorb the same wavelengths of light in the same manner. Thus, the feature size that scatters a particular wavelength of light desirable for one type of silicon layer (e.g., amorphous silicon 5′) may not be desirable and/or sufficient to improve the absorption in another type of silicon layer (e.g., micro-crystalline silicon 5″). Thus, it will be appreciated by those skilled in the art that it would be advantageous in certain embodiments to be able to produce more than one type of feature size in a textured TCO-based layer, so that the scattering of different wavelengths of light can be enhanced by the same TCO-based layer.

It has been found that providing a textured TCO-based layer with more than one type of feature size is particularly advantageous for micro-morph silicon solar cells and/or other solar cells comprising multi-layered semiconductors, wherein the feature sizes correspond to the wavelengths effectively absorbed by the at least two layers and/or portions (micro-crystalline and amorphous) of the micro-morph silicon solar cell.

Thus, in certain example embodiments, a textured layer and/or coating with at least two feature sizes is provided, wherein at least one type of feature is comparable in size to the wavelength of solar light absorbed by the crystalline portion of the micro-morph thin-film silicon solar cell, and the other type is comparable in size to the wavelength of solar light absorbed by the amorphous portion of the micro-morph thin-film silicon solar cell.

In certain example embodiments, double-agent etchants may be used, advantageously resulting in a texturing of a transparent conductive oxide (TCO) layer that has different types of feature sizes. As indicated above, using a TCO-based layer that is textured such that it has different feature sizes may improve the efficiency of the solar cell in some cases. In certain example embodiments, using double-agent etchants and/or more than one type of etchant may advantageously produce a TCO-based layer with more than one type of feature size.

In certain embodiments, the TCO-based layer may comprise, or consist essentially of, zinc oxide (e.g., ZnₓO_{y}). In other example embodiments, the TCO-based layer may comprise, or consist essentially of, zinc oxide that is doped. The dopant may be aluminum, gallium, boron, and/or any other suitable materials. In certain example embodiments, the textured TCO-based layer may comprise zinc oxide doped with from about 0.5 to 10% (wt. %) of the dopant, and all sub-ranges therein, preferably from about 0.5 to 3%, more preferably from about 1 to 2%, and in certain exemplary embodiments, the TCO-based layer may comprise about 2% by weight of the dopant. In other example embodiments, the TCO-based layer may comprise any appropriate transparent conductive oxide.

The etching of the TCO-based layer(s) in certain example embodiments may be textured by wet chemical techniques including, for example, spraying, wet spraying, dipping, meniscus coating, etc., in different example implementations. In some cases, the surface of the TCO-based layer may be etched with a double-agent etchant, such as a mixture of two or more acids.

The double-agent etchant, in certain example embodiments, may comprise dilute acetic acid (e.g., CH₃COOH) and ammonium chloride (e.g., NH₄Cl). In certain example embodiments, the dilute acetic acid and ammonium chloride may be in an aqueous solution. A double-agent etchant comprising dilute acetic acid and ammonium chloride may be used for etching any TCO-based layer. However, it has been advantageously found that when using dilute acetic acid and ammonium chloride to texture a ZnO:Al-based layer, the addition of the ammonium chloride may improve the size and smoothness of the features on the textured surface and may also result in the formation of a wider distribution of ZnO:Al feature sizes in certain example embodiments. In certain example embodiments, the ratio of ammonium chloride to acetic acid in an aqueous solution ranges from (0.1-5%) NH₄Cl to (0.5-10%) CH₃COOH.

In certain example embodiments, the surface of a TCO-based layer may be textured using a mixture of dilute acetic acid and phosphoric acid. The phosphoric acid may be dilute, as well, in certain instances. In certain example embodiments, the ratio of phosphoric acid to acetic acid in an aqueous solution ranges from (0.1-5%) H₃PO₄ to (0.5-10%) CH₃COOH.

The feature sizes of the textured layer/film in different embodiments may be from about 0.5 to 3 microns in width or diameter, more preferably from about 0.7 to 1.2 microns, even more preferably from about 0.9 to 1.1 microns, and in certain exemplary embodiments, the features may be about 1 micron in diameter. The height, measured from peak to valley, of the features of the textured layer/film in different embodiments may be from about 0.01 to 1 micron, more preferably from about 0.03 to 0.5, even more preferably from about 0.05 to 0.3, and most preferably from about 0.1 to 0.2, with an example exemplary height being about 0.15 microns.

The TCO-based layer/film may be deposited on a float glass substrate, in certain example embodiments. The float glass may have a reduced iron content in other examples.

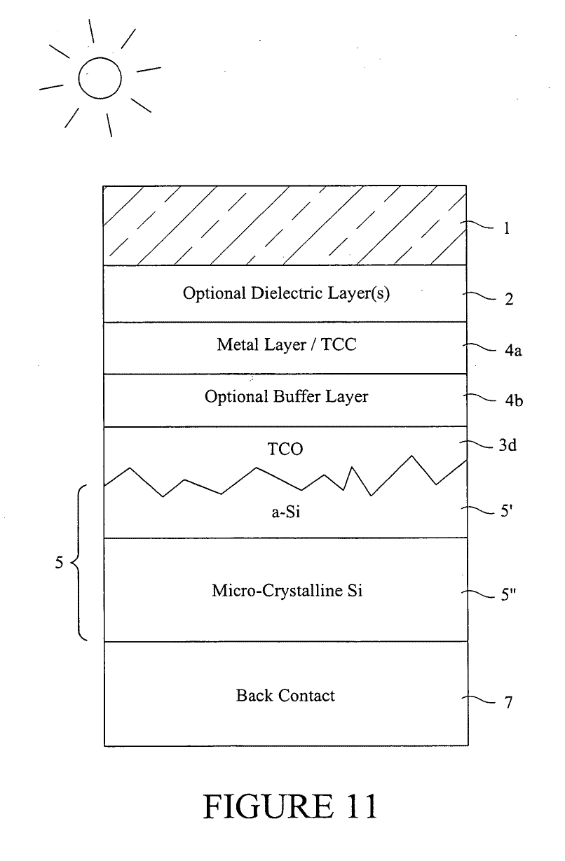

The TCO-based layer/film may further be provided over a glass substrate coated with a thin, metallic, transparent conductive coating (TCC) in other cases. An example of this arrangement is provided in FIG. 11. FIG. 11 shows a front glass substrate/superstrate 1. Optional dielectric layer(s) 2 may be deposited over glass substrate 1. A thin, metal, transparent conductive layer 4a and/or coating may be deposited over dielectric layer(s) 2. An optional buffer layer 4b may be provided between layer 4a and TCO-based layer 3d. Other layers may be provided between the substrate and the TCO, and/or elsewhere.

The TCO-based layer may be deposited via a magnetron target, in certain embodiments. The target may be metallic or ceramic, in different implementations. The sputtering target may deposit via reactive sputtering in further example embodiments. In various embodiments, the target may comprise zinc, and optionally one or more of Al, Ga, B, and/or the like. In other embodiments the target may further comprise oxygen.

In certain example embodiments, a textured TCO-based layer is provided, wherein the surface of the TCO-based layer is textured with features of at least two different sizes. In further example embodiments, the textured surface of the TCO may have features of many different sizes.

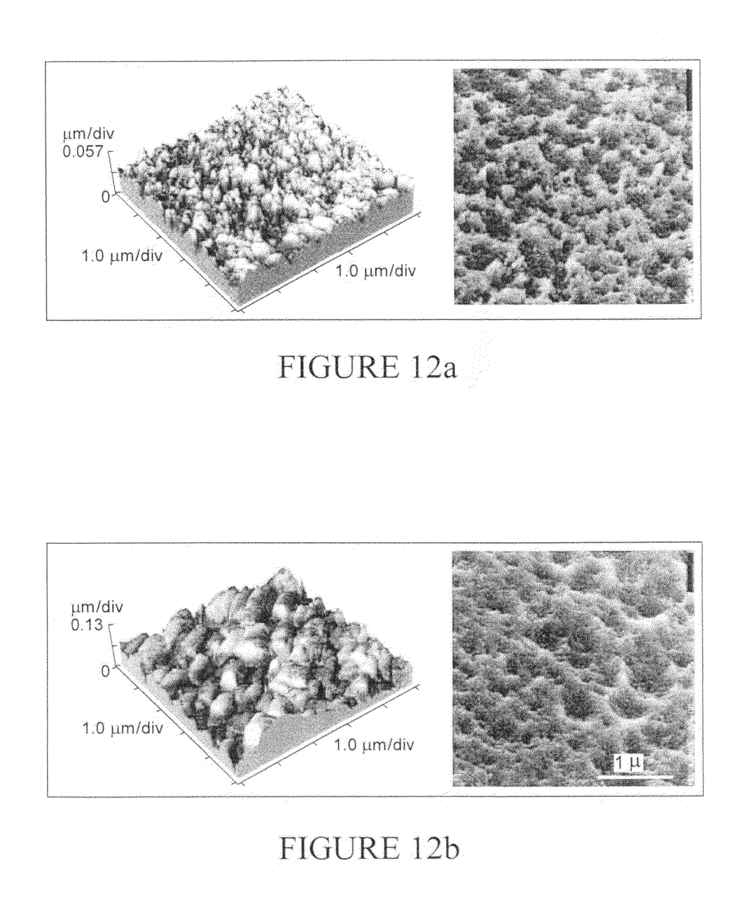

FIGS. 12a-b compare AFM and SEM images where single-agent and double-agent etchants were used to texture the surface of magnetron-sputtered ZnO:Al, respectively. More particularly, FIG. 12a shows AFM and SEM images of the effect of a single-agent (diluted acid; e.g., HCl, acetic acid, etc) on the textured surface of magnetron-sputtered ZnO:Al, whereas FIG. 12b AFM and SEM images of the effect of a double-agent etchant (acetic acid and phosphoric acids; acetic acid and ammonium chloride; etc) on the textured surface of magnetron-sputtered ZnO:Al.

Certain example embodiments have been described in connection with multiple agent etchants. Thus, it will be appreciated that such chemical compositions may include two, three, or more etchants. For instance, in certain example embodiments, acetic acid, phosphoric acid, ammonium chloride, and/or other etchants may be used. Any suitable buffers may be used in connection with the multiple etchants. HCl also may be used as an etchant in certain example embodiments. The use of multiple etchants has been found to be advantageous because the multiple etchants are able to attack different directions of the crystal lattice, resulting in the creation of different types of features suitable for improving light scattering in ways desirable for semiconductors.

Acetic acid as a primary etchant has been found to be advantageous in certain example embodiments because of its processability. Indeed, acetic acid has a wider process window, scales well, and has a reduced sensitivity to temperature changes (e.g., in a 30-40 degrees C. example range)—especially as compared to HCl. Because acetic acid scales well, it may be used over larger substrates. In addition, because it is a comparatively mild acid, it does not have to be diluted to a very low concentration which often is difficult to perform and control, e.g., when closed loop processing is performed. It also may be comparatively less harmful, easier to remove salts and/or other byproducts, etc.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a solar cell, the method comprising:
sputter-depositing a layer comprising zinc oxide on a glass substrate;
etching the layer comprising zinc oxide with at least a double-agent etchant comprising at least two acids in order to texture a surface of the layer comprising zinc oxide and in order to produce at least first and second feature types having different respective feature sizes;
forming a first semiconductor layer comprising amorphous silicon, directly or indirectly, on the layer comprising zinc oxide; and
forming a second semiconductor layer comprising micro-crystalline silicon over and contacting the first semiconductor layer in making the solar cell.

2. The method of claim 1, wherein at least one of the feature types has a diameter of from about 0.7 to 1.2 microns.

3. The method of claim 2, wherein at least one of the feature types has a diameter of from about 0.9 to 1.1 microns.

4. The method of claim 1, wherein at least one of the feature types has a height of from about 0.05 to 0.3 microns.

5. The method of claim 4, wherein at least one of the feature types has a height of from about 0.1 to 0.2 microns.

6. The method of claim 1, wherein the double-agent etchant comprises dilute acetic acid and ammonium chloride.

7. The method of claim 6, wherein the ratio of ammonium chloride to acetic acid in an aqueous solution ranges from (0.1-5%) NH₄Cl to (0.5-10%) CH₃COOH.

8. The method of claim 1, wherein the double-agent etchant comprises dilute acetic acid and phosphoric acid.

9. The method of claim 8, wherein the ratio of phosphoric acid to acetic acid in an aqueous solution ranges from (0.1-5%) H₃PO₄ to (0.5-10%) CH₃COOH.

10. The method of claim 1, wherein the double-agent etchant comprises at least two weak acids.

11. The method of claim 1, wherein the layer comprising zinc oxide is doped with a dopant in an amount of from about 0.5 to 10% by weight.

12. The method of claim 13, wherein the layer comprising zinc oxide is doped with at least one of Al, Ga, and B.

13. A method of making a solar cell, the method comprising:
etching a layer comprising a transparent conductive oxide (TCO) disposed on a glass substrate with an etchant comprising at least two acids in order to texture a surface of the TCO-based layer;
forming a first semiconductor layer comprising amorphous silicon, directly or indirectly, on the TCO-based layer; and
forming a second semiconductor layer comprising micro-crystalline over and contacting the layer comprising amorphous silicon in making the solar cell;
wherein the surface of the layer comprising the TCO, post-etching, includes at least first and second feature types, the first feature type being sized so as to scatter light in a first range corresponding to the first semiconductor layer and the second feature type being sized so as to scatter light in a second range corresponding to the second semiconductor layer.

14. The method of claim 13, wherein at least one of the feature types has a diameter of from about 0.9 to 1.1 microns.

15. The method of claim 13, wherein at least one of the feature types has a height of from about 0.1 to 0.2 microns.

16. The method of claim 13, wherein the etchant comprises dilute acetic acid and ammonium chloride.

17. The method of claim 16, wherein the ratio of ammonium chloride to acetic acid in an aqueous solution ranges from (0.1-5%) NH₄Cl to (0.5-10%) CH₃COOH.

18. The method of claim 13, wherein the etchant comprises dilute acetic acid and phosphoric acid.

19. The method of claim 18, wherein the ratio of phosphoric acid to acetic acid in an aqueous solution ranges from (0.1-5%) H₃PO₄ to (0.5-10%) CH₃COOH.

20. The method of claim 13, wherein the etchant comprises at least two weak acids.

21. The method of claim 13, wherein the TCO-based layer is doped with at least one dopant in an amount of from about 0.5 to 10% (by weight).

22. The method of claim 13, wherein the TCO-based layer is doped with at least one of Al, Ga, and B.

23. A solar cell comprising
a glass substrate;
a textured transparent conductive oxide (TCO)-based layer comprising zinc oxide;
a first semiconductor layer comprising amorphous silicon; and
a second semiconductor layer comprising micro-crystalline silicon,
wherein the surface of the textured TCO-based layer includes at least first and second feature types, the first feature type being sized so as to scatter light in a first range corresponding to the first semiconductor layer and the second feature type being sized so as to scatter light in a second range corresponding to the second semiconductor layer.
